(19) United States
(12) Patent Application Publication
(10) Pub. No.: US 2019/0097175 A1
(43) Pub. Date: Mar. 28, 2019

(54) THIN FILM ENCAPSULATION SCATTERING LAYER BY PECVD

(71) Applicant: Applied Materials, Inc., Santa Clara, CA (US)

(72) Inventors: Wen-Hao WU, San Jose, CA (US); Jrjyan Jerry CHEN, Campbell, CA (US)

(21) Appl. No.: 15/719,067

(22) Filed: Sep. 28, 2017

(51) Int. Cl. H01L 51/52; H01L 51/56; C23C 16/34; C23C 16/30; C23C 16/455; C23C 16/50

(52) U.S. Cl. CPC H01L 51/5268; H01L 51/56; C23C 16/345; H01L 51/502; C23C 16/45557; C23C 16/50; C23C 16/308

(57) ABSTRACT

Embodiments described herein generally related to a method for manufacturing an encapsulating structure for a display device, more particularly, for manufacturing a TFE structure including a light scattering layer. The TFE structure further includes one or more barrier layers. All layers of the TFE structure are formed in a PECVD apparatus. The light scattering layer is formed by a PECVD process, in which a silicon containing precursor and a nitrogen containing precursor are introduced into the PECVD apparatus. The flow rate of the silicon containing precursor is equal to or greater than the flow rate of the nitrogen containing precursor. The light scattering layer enhances light out-coupling from a light emitting device disposed under the TFE structure.

### BACKGROUND

### Field

Embodiments described herein generally relate to a method for manufacturing an encapsulating structure for a display device, more particularly, for manufacturing a thin film encapsulation (TFE) structure including a light scattering layer.

### Description of the Related Art

A display device, such as an organic light emitting diode (OLED) or a quantum-dot device, is used in television screens, computer monitors, mobile phones, other hand-held devices, etc. for displaying information. OLED devices have gained significant interest recently in display applications due to their faster response time, larger viewing angles, higher contrast, lighter weight, low power and amenability to flexible substrates such as compared to liquid crystal displays (LCD).

OLED devices may have a limited lifetime, characterized by a decrease in electroluminescence efficiency and an increase in drive voltage. A main reason for the degradation of OLED devices is the formation of non-emissive dark spots due to moisture or oxygen ingress. For this reason, OLED devices are typically encapsulated by a buffer layer sandwiched between barrier layers. It has been observed that the current encapsulation layers may have difficulties in light out-coupling from the OLED.

Therefore, an improved method for encapsulating a display device is needed.

### SUMMARY

Embodiments described herein generally related to a method for manufacturing an encapsulating structure for a display device, more particularly, for manufacturing a TFE structure including a light scattering layer. In one embodiment, a method includes depositing a barrier layer over a light emitting device in a plasma enhanced chemical vapor deposition (PECVD) chamber, and depositing a light scattering layer over the light emitting device in the PECVD chamber, wherein the light scattering layer is deposited by introducing a silicon containing precursor and a nitrogen containing precursor into the PECVD chamber, wherein a flow rate of the silicon containing precursor is equal to or greater than a flow rate of the nitrogen containing precursor.

In one embodiment, a method includes depositing a TFE structure over a light emitting device in a PECVD chamber, wherein depositing the TFE structure includes depositing a barrier layer over a light emitting device in a PECVD chamber, and depositing a light scattering layer over the light emitting device in the PECVD chamber, wherein the light scattering layer is deposited by introducing silane gas and ammonia gas into the PECVD chamber, wherein a flow rate of the silane gas is equal to or greater than a flow rate of the ammonia gas.

In one embodiment, a method includes depositing a TFE structure over a light emitting device in a PECVD chamber, wherein depositing the TFE structure includes depositing a first barrier layer over the light emitting device, depositing a buffer layer over the first barrier layer, depositing a second barrier layer over the buffer layer, and depositing a light scattering layer over the light emitting device prior to depositing the first barrier layer, after depositing the first barrier layer but before depositing the buffer layer, after depositing the buffer layer but before depositing the second barrier layer, or after depositing the second barrier layer, wherein the light scattering layer is deposited by introducing a silicon containing precursor and a nitrogen containing precursor into the plasma enhanced chemical vapor deposition chamber, wherein a flow rate of the silicon containing precursor is equal to or greater than a flow rate of the nitrogen containing precursor.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic, cross-sectional view of a PECVD apparatus that may be used to form a TFE structure described herein, according to one embodiment described herein.

FIG. 1B is a schematic top view of the PECVD apparatus of FIG. 1A, according to one embodiment described herein.

FIGS. 2A-2D are schematic cross-sectional side views of a portion of a display device including a TFE structure having a light scattering layer, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally related to a method for manufacturing an encapsulating structure for a display device, more particularly, for manufacturing a TFE structure including a light scattering layer. The TFE structure further includes one or more barrier layers. All layers of the TFE structure are formed in a PECVD apparatus. The light scattering layer is formed by a PECVD process, in which a silicon containing precursor and a nitrogen containing precursor are introduced into the PECVD apparatus. The flow rate of the silicon containing precursor is equal to or greater than the flow rate of the nitrogen containing precursor. The light scattering layer enhances light out-coupling from a light emitting device disposed under the TFE structure.

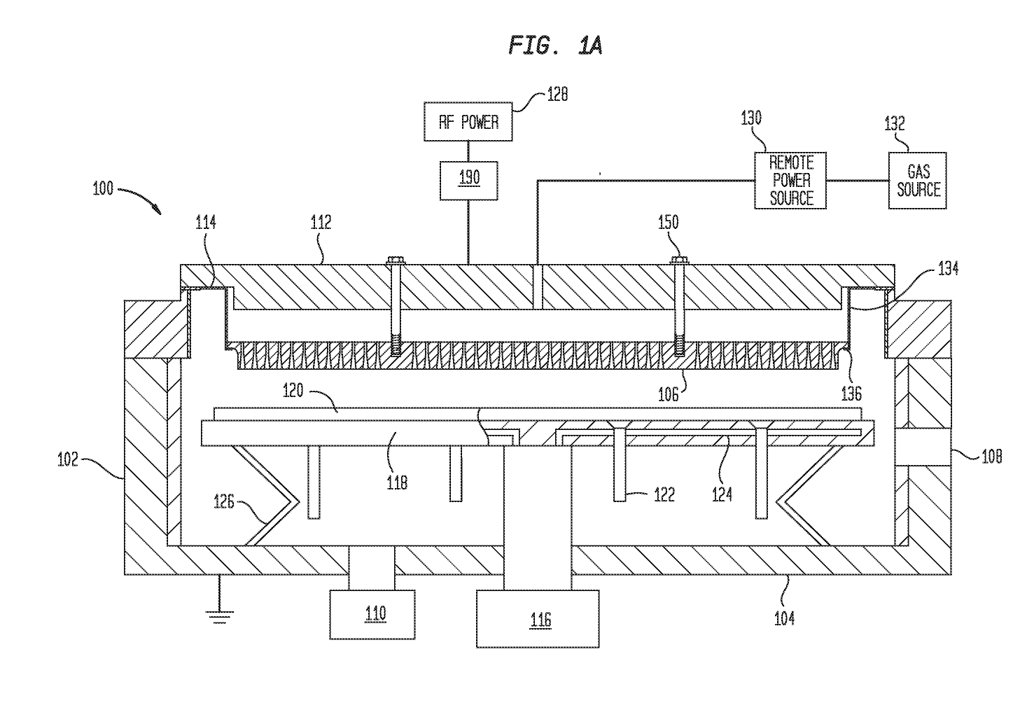

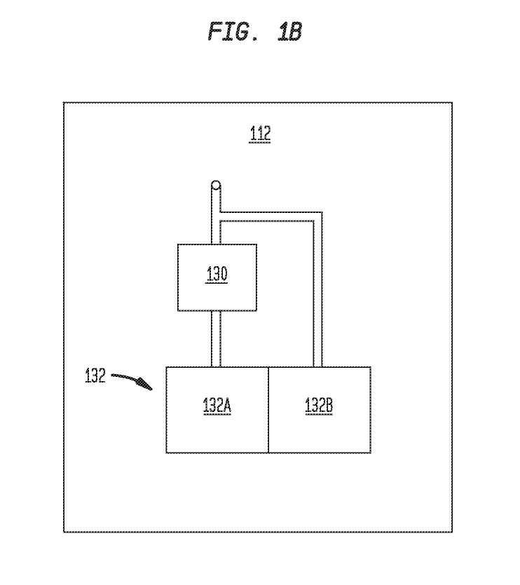

FIG. 1A is a schematic, cross-sectional view of a plasma enhanced chemical vapor deposition (PECVD) apparatus that may be used to form a TFE structure described herein. The PECVD apparatus includes a chamber 100 in which one or more layers may be deposited onto a substrate 120. The chamber 100 generally includes one or more walls 102, a bottom 104 and a showerhead 106 which define a process volume. The showerhead 106 is coupled to a backing plate 112 by one or more fastening mechanism 150 to help prevent sag and/or control the straightness/curvature of the showerhead 106.

A substrate support 118 is disposed within the process volume. The process volume is accessed through a slit valve opening 108 such that the substrate 120 may be transferred in and out of the chamber 100. The substrate support 118 is coupled to an actuator 116 to raise and lower the substrate support 118. Lift pins 122 are moveably disposed through the substrate support 118 to move the substrate 120 to and from the substrate receiving surface of the substrate support 118. The substrate support 118 also includes heating and/or cooling elements 124 to maintain the substrate support 118 at a predetermined temperature.

A gas source 132 is coupled to the backing plate 112 to provide gas through gas passages in the showerhead 106 to a processing area between the showerhead 106 and the substrate 120. A vacuum pump 110 is coupled to the chamber 100 to maintain the process volume at a predetermined pressure. An RF source 128 is coupled through a match network 190 to the backing plate 112 and/or to the showerhead 106 to provide an RF current to the showerhead 106. The RF current creates an electric field between the showerhead 106 and the substrate support 118 so that a plasma may be generated from the gases between the showerhead 106 and the substrate support 118. The substrate support 118 also includes RF return straps 126 to provide an RF return path at the periphery of the substrate support 118.

A remote plasma source 130, such as an inductively coupled remote plasma source 130, is coupled between the gas source 132 and the backing plate 112. Between processing substrates, a cleaning gas may be provided to the remote plasma source 130 so that a remote plasma is generated. The radicals from the remote plasma may be provided to the chamber 100 to clean the chamber 100 components. The cleaning gas may be further excited by the RF source 128 provided to the showerhead 106.

The showerhead 106 is additionally coupled to the backing plate 112 by showerhead suspension 134. In one embodiment, the showerhead suspension 134 is a flexible metal skirt. The showerhead suspension 134 may have a lip 136 upon which the showerhead 106 may rest. The backing plate 112 may rest on an upper surface of a ledge 114 coupled with the chamber walls 102 to seal the chamber 100.

FIG. 1B is a schematic top view of the PECVD apparatus of FIG. 1A, according to one embodiment described herein. As shown in FIG. 1B, the gas source 132 includes a first portion 132A and a second portion 132B. The first portion 132A feeds gas directly to the remote plasma source 130 and then to the chamber 100 through the backing plate 112. Second portion 132B delivers gas to the chamber 100 through the backing plate 112 by bypassing the remote plasma source 130.

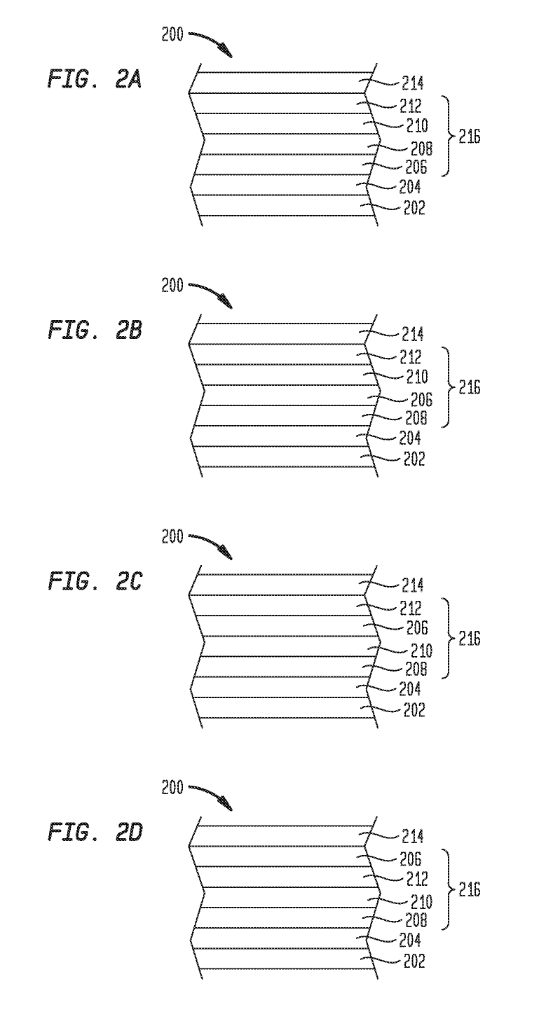

FIGS. 2A-2D are schematic cross-sectional side views of a portion of a display device 200 including a TFE structure 216 having a light scattering layer 206, according to embodiments described herein. As shown in FIG. 2A, the display device 200 includes a substrate 202, a light emitting device 204, the TFE structure 216, and the cover substrate 214. The substrate 202 may be made of glass or plastic, such as polyethyleneterephthalate (PET) or polyethyleneterephthalate (PEN). The light emitting device 204 is disposed over the substrate 202. The light emitting device 204 may be an OLED structure or a quantum-dot structure. A contact layer (not shown) may be disposed between the light emitting device 204 and the substrate 202, and the contact layer is in contact with the substrate 202 and the light emitting device 204.

The TFE structure 216 encapsulates the light emitting device 204 (the portion of the display device 200 shown in FIGS. 2A-2D does not show that the vertical sides of the light emitting device 204 are covered by the TFE structure 216). The TFE structure 216 includes the light scattering layer 206 and one or more barrier layers. In one embodiment, as shown in FIG. 2A, the TFE structure 216 includes the light scattering layer 206 disposed on the light emitting device 204, a first barrier layer 208 disposed on the light scattering layer 206, a buffer layer 210 disposed on the first barrier layer 208, and a second barrier layer 212 disposed on the buffer layer 210. In some embodiments, a buffer adhesion layer (not shown) is disposed between the first barrier layer 208 and the buffer layer 210, and a stress reduction layer (not shown) is disposed between the buffer layer 210 and the second barrier layer 212.

The light scattering layer 206 is a dielectric layer including a major surface having a plurality of bumps. The major surface has a surface roughness root mean square (RMS) ranging from about 50 Angstroms to about 200 Angstroms. Each bump of the plurality of bumps has a dimension close to visible wavelength range, such as from about 400 nanometers (nm) to about 700 nm. The bumpy major surface of the light scattering layer 206 is glossy to hazy, having a haze ratio of less than five percent. The light scattering layer may be silicon nitride (SiN) or silicon oxynitride (SiON). The bumpy major surface of the light scattering layer 206 enhances light out-coupling from the light emitting device 204. The light scattering layer 206 has a thickness ranging from about 0.1 microns to about 1 micron.

The first barrier layer 208 is a dielectric layer, such as SiN, SiON, silicon dioxide (SiO₂), aluminum oxide (Al₂O₃), aluminum nitride (AlN), or other suitable dielectric layers. In one embodiment, the first barrier layer 208 is silicon nitride. The first barrier layer has a thickness ranging from about 0.5 microns to about 1 micron. The first barrier layer 208 is different from the light scattering layer 206 in that the major surface of the first barrier layer 208 is smoother than the major surface of the light scattering layer 206, even though the first barrier layer 208 and the light scattering layer 206 can be made of the same material. The buffer layer 210 may be plasma-polymerized hexamethyldisiloxane (pp-HMDSO), such as fluorinated plasma-polymerized hexamethyldisiloxane (pp-HMDSO:F). Alternatively, the buffer layer 210 may be a polymer material composed by hydrocarbon compounds. The polymer material may have a formula CₓH_{y}O_{z}, wherein x, y and z are integers. In one embodiment, the buffer layer 210 may be selected from a group consisting of polyacrylate, parylene, polyimides, polytetrafluoroethylene, copolymer of fluorinated ethylene propylene, perfluoroalkoxy copolymer resin, copolymer of ethylene and tetrafluoroethylene, parylene. In one specific example, the buffer layer 210 is polyacrylate or parylene. The buffer layer 210 has a thickness ranging from about 2 microns to about 5 micron. The second barrier layer 212 may be made of the same material as the first barrier layer 208. The second barrier layer 212 has a thickness ranging from about 0.5 microns to about 1 micron.

In one embodiment, the light scattering layer 206, the first barrier layer 208, the buffer layer 210, and the second barrier layer 212 are deposited in a single PECVD chamber, such as the chamber 100 shown in FIG. 1A. Purging of the PECVD chamber may be performed between cycles to minimize the risk of contamination. The single chamber process is advantageous in reducing cycle times as well as reducing the number of chambers (and equipment costs) of using a multiple chamber process. In one embodiment, the TFE structure 216 is formed by placing the substrate 202 including the light emitting device 204 into the chamber 100. The light scattering layer 206 is deposited on the light emitting device 204 in the chamber 100 by a PECVD process. The PECVD process for depositing the light scattering layer 206 includes introducing a silicon containing precursor and a nitrogen containing precursor into the PECVD chamber, and the flow rate of the silicon containing precursor is equal to or greater than the flow rate of the nitrogen containing precursor. In one embodiment, the light scattering layer 206 is SiN, and SiH₄, NH₃, N₂ and H₂ gases are introduced into the chamber 100 for depositing the SiN light scattering layer 206. The flow rate ratio of the SiH₄ gas to the NH₃ gas ranges from about 1 to 2.5, and the flow rate ratio of the N₂ gas to the H₂ gas ranges from about 5 to 15. The chamber pressure ranges from about 1000 mTorr to about 2000 mTorr. After the light scattering layer is deposited, the chamber 100 is purged so no precursors are remained in the chamber 100.

The first barrier layer 208 is deposited on the light scattering layer 206 by a PECVD process. In one embodiment, one or more precursors are flowed into the chamber 100, and the first barrier layer 208 is deposited at 85 degrees Celsius in the presence of a RF plasma at 0.006 W/mm² and at a pressure of 1600 mTorr. In one embodiment, the first barrier layer is SiN, and the one or more precursors include silane (SiH₄), ammonia (NH₃), nitrogen (N₂) and hydrogen (H₂) gases. The SiH₄, NH₃, N₂ and H₂ gases are delivered at 0.0015, 0.0034, 0.0086, and 0.014 sccm/mm², respectively. The flow rate of the SiH₄ gas is less than the flow rate of the NH₃ gas, and the flow rate of the N₂ gas is less than the flow rate of the H₂ gas. In some embodiments, the light scattering layer 206 and the first barrier layer 308 are both made of SiN. Even though the precursors used for depositing the light scattering layer 206 are the same as the precursors used for depositing the first barrier layer 208, the light scattering layer 206 has a bumpy major surface compared to the first barrier layer 208 due to the different precursor flow rates. There may not be a purge step between depositing the light scattering layer 206 and the first barrier layer 208 if the light scattering layer 206 and the first barrier layer 208 are made of the same material.

The buffer layer 210 is deposited over the first barrier layer 208 in the chamber 100 by a PECVD process. A purge step is performed after depositing the first barrier layer 208 prior to depositing the buffer layer 210, because different precursors are being used for the deposition processes. After the buffer layer 210 is deposited, another purge step is performed. The second barrier layer 212 is deposited over the buffer layer 210, and the second barrier layer 212 may be deposited under the same process conditions as the first barrier layer 208.

After the TFE 216 is deposited over the substrate 202, the cover substrate 214 is deposited over the TFE structure 216. The cover substrate 214 may be made of a same material as the substrate 202.

FIG. 2B is schematic cross-sectional side views of a portion of the display device 200 including the TFE structure 216 having the light scattering layer 206, according to another embodiment described herein. As shown in FIG. 2B, the display device 200 includes the substrate 202, the light emitting device 204, the TFE structure 216, and the cover substrate 214. A contact layer (not shown) may be disposed between the light emitting device 204 and the substrate 202, and the contact layer is in contact with the substrate 202 and the light emitting device 204.

In one embodiment, as shown in FIG. 2B, the TFE structure 216 includes the first barrier layer 208 disposed on the light emitting device 204, the light scattering layer 206 disposed on the first barrier layer 208, the buffer layer 210 disposed on the light scattering layer 206, and the second barrier layer 212 disposed on the buffer layer 210. The first barrier layer 208, the light scattering layer 206, the buffer layer 210, and the second barrier layer 212 are deposited in a single PECVD chamber, such as the chamber 100 shown in FIG. 1A. The cover substrate 214 is disposed on the TFE structure 216. In some embodiments, a buffer adhesion layer (not shown) is disposed between the light scattering layer 206 and the buffer layer 210, and a stress reduction layer (not shown) is disposed between the buffer layer 210 and the second barrier layer 212.

In one embodiment, the TFE structure 216 is formed by placing the substrate 202 including the light emitting device 204 into the chamber 100. The first barrier layer 208 is deposited over the light emitting device 204 in the chamber 100. After the first barrier layer 208 is deposited, an optional purge step is performed. The light scattering layer 206 is deposited over the first barrier layer 208 in the chamber 100. After the light scattering layer 206 is deposited, a purge step is performed. The buffer layer 210 is deposited over the light scattering layer 206 in the chamber 100. After the buffer layer 210 is deposited, a purge step is performed. The second barrier layer 212 is deposited over the buffer layer 210. After the TFE 216 is deposited over the substrate 202, the cover substrate 214 is deposited over the TFE structure 216. The cover substrate 214 may be made of a same material as the substrate 202.

FIG. 2C is schematic cross-sectional side views of a portion of the display device 200 including the TFE structure 216 having the light scattering layer 206, according to another embodiment described herein. As shown in FIG. 2C, the display device 200 includes the substrate 202, the light emitting device 204, the TFE structure 216, and the cover substrate 214. A contact layer (not shown) may be disposed between the light emitting device 204 and the substrate 202, and the contact layer is in contact with the substrate 202 and the light emitting device 204.

In one embodiment, as shown in FIG. 2C, the TFE structure 216 includes the first barrier layer 208 disposed on the light emitting device 204, the buffer layer 210 disposed on the first barrier layer 208, the light scattering layer 206 disposed on the buffer layer 210, and the second barrier layer 212 disposed on the light scattering layer 206. The first barrier layer 208, the buffer layer 210, the light scattering layer 206, and the second barrier layer 212 are deposited in a single PECVD chamber, such as the chamber 100 shown in FIG. 1A. The cover substrate 214 is disposed on the TFE structure 216. In some embodiments, a buffer adhesion layer (not shown) is disposed between the first barrier layer 208 and the buffer layer 210, and a stress reduction layer (not shown) is disposed between the buffer layer 210 and the light scattering layer 206.

In one embodiment, the TFE structure 216 is formed by placing the substrate 202 including the light emitting device 204 into the chamber 100. The first barrier layer 208 is deposited over the light emitting device 204 in the chamber 100. After the first barrier layer 208 is deposited, a purge step is performed. The buffer layer 210 is deposited over the first barrier layer 208 in the chamber 100. After the buffer layer 210 is deposited, a purge step is performed. The light scattering layer 206 is deposited over the buffer layer 210 in the chamber 100. After the light scattering layer 206 is deposited, an optional purge step is performed. The second barrier layer 212 is deposited over the light scattering layer 206. After the TFE 216 is deposited over the substrate 202, the cover substrate 214 is deposited over the TFE structure 216. The cover substrate 214 may be made of a same material as the substrate 202.

FIG. 2D is schematic cross-sectional side views of a portion of the display device 200 including the TFE structure 216 having the light scattering layer 206, according to another embodiment described herein. As shown in FIG. 2D, the display device 200 includes the substrate 202, the light emitting device 204, the TFE structure 216, and the cover substrate 214. A contact layer (not shown) may be disposed between the light emitting device 204 and the substrate 202, and the contact layer is in contact with the substrate 202 and the light emitting device 204.

In one embodiment, as shown in FIG. 2D, the TFE structure 216 includes the first barrier layer 208 disposed on the light emitting device 204, the buffer layer 210 disposed on the first barrier layer 208, the second barrier layer 212 disposed on the buffer layer 210, and the light scattering layer 206 disposed on the second barrier layer 212. The first barrier layer 208, the buffer layer 210, the second barrier layer 212, and the light scattering layer 206 are deposited in a single PECVD chamber, such as the chamber 100 shown in FIG. 1A. The cover substrate 214 is disposed on the TFE structure 216. In some embodiments, a buffer adhesion layer (not shown) is disposed between the first barrier layer 208 and the buffer layer 210, and a stress reduction layer (not shown) is disposed between the buffer layer 210 and the second barrier layer 212.

In one embodiment, the TFE structure 216 is formed by placing the substrate 202 including the light emitting device 204 into the chamber 100. The first barrier layer 208 is deposited over the light emitting device 204 in the chamber 100. After the first barrier layer 208 is deposited, a purge step is performed. The buffer layer 210 is deposited over the first barrier layer 208 in the chamber 100. After the buffer layer 210 is deposited, a purge step is performed. The second barrier layer 212 is deposited over the buffer layer 210. After the second barrier layer 212 is deposited, an optional purge step is performed. The light scattering layer 206 is deposited over the second barrier layer 212 in the chamber 100. After the TFE 216 is deposited over the substrate 202, the cover substrate 214 is deposited over the TFE structure 216. The cover substrate 214 may be made of a same material as the substrate 202.

In summary, a method for depositing a TFE structure including a light scattering layer is disclosed. The light scattering layer enhances light out-coupling from a light emitting device disposed under the TFE structure. The light scattering layer is deposited by a PECVD process, and the remaining layers of the TFE structure are also deposited by PECVD processes. Thus, the light scattering layer and the remaining layers of the TFE structure are deposited in a single PECVD chamber. The single chamber process is advantageous in reducing cycle times as well as reducing the number of chambers (and equipment costs) of using a multiple chamber process.

While the foregoing is directed to embodiments of the disclosure, other and further embodiments may be devised without departing from the basic scope thereof, and the scope thereof is determined by the claims that follow.

1. A method, comprising:
depositing a barrier layer over a light emitting device in a plasma enhanced chemical vapor deposition chamber; and
depositing a light scattering layer on and in physical contact with the barrier layer over the light emitting device in the plasma enhanced chemical vapor deposition chamber, wherein the light scattering layer is deposited by introducing a silicon containing precursor and a nitrogen containing precursor into the plasma enhanced chemical vapor deposition chamber, wherein a flow rate of the silicon containing precursor is equal to or greater than a flow rate of the nitrogen containing precursor.

2. The method of claim 1, wherein a flow rate ratio of the silicon containing precursor to the nitrogen containing precursor ranges from about 1 to 2.5.

3. The method of claim 2, wherein the silicon containing precursor is silane gas and the nitrogen containing precursor is ammonia gas.

4. The method of claim 3, wherein the depositing the light scattering layer further comprises introducing nitrogen gas and hydrogen gas into the plasma enhanced chemical vapor deposition chamber.

5. The method of claim 4, wherein a flow rate ratio of the nitrogen gas to the hydrogen gas ranges from about 5 to 15.

6. The method of claim 1, wherein the light scattering layer comprises silicon nitride or silicon oxynitride.

7. The method of claim 1, wherein the light scattering layer comprises a major surface having a plurality of bumps.

8. The method of claim 7, wherein each bump of the plurality of bumps has a dimension ranging from about 400 nm to about 700 nm.

9. A method, comprising:
depositing a thin film encapsulation structure over a light emitting device in a plasma enhanced chemical vapor deposition chamber, wherein depositing the thin film encapsulation structure comprises:
depositing a barrier layer on and in physical contact with the light emitting device; and
depositing a light scattering layer on and in physical contact with the barrier layer over the light emitting device, wherein the light scattering layer is deposited by introducing silane gas and ammonia gas into the plasma enhanced chemical vapor deposition chamber, wherein a flow rate of the silane gas is equal to or greater than a flow rate of the ammonia gas.

10. The method of claim 9, wherein the light emitting device is an organic light emitting diode or a quantum-dot device.

11. The method of claim 9, wherein the light scattering layer comprises silicon nitride or silicon oxynitride.

12. The method of claim 9, wherein the light scattering layer comprises a major surface having a plurality of bumps.

13. The method of claim 12, wherein each bump of the plurality of bumps has a dimension ranging from about 400 nm to about 700 nm.

14-20. (canceled)

21. A method, comprising:
depositing a thin film encapsulation structure over a light emitting device in a plasma enhanced chemical vapor deposition chamber, wherein depositing the thin film encapsulation structure comprises:
depositing a light scattering layer on and in physical contact with the light emitting device, wherein the light scattering layer is formed with a major surface having a plurality of bumps;
depositing a first barrier layer on the light scattering layer;
depositing a buffer layer over the first barrier layer; and
depositing a second barrier layer over the buffer layer.

22. The method of claim 21, wherein the plurality of bumps have a surface roughness root mean square (RMS) ranging from about 50 Angstroms to about 200 Angstroms.

23. The method of claim 21, wherein each bump of the plurality of bumps has a dimension ranging from about 400 nm to about 700 nm.

24. The method of claim 21, wherein the light scattering layer comprises silicon nitride or silicon oxynitride, and the first barrier layer and the second barrier layer comprise silicon nitride, silicon oxynitride, silicon dioxide, aluminum oxide or aluminum nitride.

25. The method of claim 24, wherein the light scattering layer and the first barrier layer are formed from the same material.

26. The method of claim 21, wherein the light scattering layer has a haze ratio of less than five percent.

27. The method of claim 21, wherein the plurality of bumps are formed by introducing a silicon containing precursor and a nitrogen containing precursor into the plasma enhanced chemical vapor deposition chamber maintained at a chamber pressure of about 1000 mTorr to about 2000 mTorr, and wherein a flow rate of the silicon containing precursor to the nitrogen containing precursor ranges from about 1 to 2.5.
